(19) United States
(12) Patent Application Publication
(10) Pub. No.: US 2023/0189446 A1
(43) Pub. Date: Jun. 15, 2023

(54) TOPOGRAPHY-BASED DEPOSITION HEIGHT ADJUSTMENT

(71) Applicant: Mycronic AB, Taby (SE)

(72) Inventors: Gustaf MARTENSSON, Solna (SE); Per-Erik GUSTAFSSON, Sundbyberg (SE)

(73) Assignee: Mycronic AB, Taby (SE)

(21) Appl. No.: 17/925,145

(22) PCT Filed: May 26, 2021
(86) PCT No.: PCT/EP2021/063963

§ 371 Date: Nov. 14, 2022

(30) Foreign Application Priority Data
May 26, 2020 (EP) 20176565.8

(51) Int. Cl. H05K 3/00; H05K 1/02; H05K 3/12; H05K 13/08

(52) U.S. Cl. CPC H05K 3/0005; H05K 1/0266; H05K 3/125; H05K 13/0813; H05K 13/086; H05K 2201/0302; H05K 2203/0528

(57) ABSTRACT

A method for mounting a component (100) on a workpiece (106), the method comprising obtaining information regarding a surface topography of at least one of a mounting surface (102) of the component and a local surface (108) of the workpiece onto which the component is to be mounted. The method further comprises forming a plurality of deposits (110) of a viscous medium on at least one of the mounting and local surfaces, wherein each of the plurality of deposits has a height (/½, /½, h3) based on the obtained information, and is formed by individually applying at least one droplet (234) of the viscous medium (232) using non-contact dispensing. The method further comprises placing the component on the substrate, such that the plurality of deposits of viscous medium forms a connection between the component and the workpiece.

### TECHNICAL FIELD

The present disclosure relates generally to the field of mounting technology. More specifically it relates to a method for mounting a component onto a workpiece, and a system for depositing a viscous medium on a workpiece and/or a component.

### BACKGROUND

In many fields of technology, such as the production of integrated circuits, components are mounted on, and connected to, workpieces using some form of viscous medium like adhesives, solder paste etc.

Components and workpieces are not always perfectly flat. During production, components and/or workpieces may become slightly bent or warped. Especially in fields in which components and/or workpieces become increasingly thinner, such as e.g. printed circuit board assembly (PCBA), the prevalence of warpage of components and workpieces may increase. These topographical features of components and workpieces may be further accentuated by treatment of the assembly comprising the component and the workpiece during or after mounting. As an example, application of energy, such as heat or light, with the purpose of melting or hardening the viscous medium, may increase warpage of the component and/or the workpiece.

Warpage may lead to a mismatch between the surfaces of the component and the workpiece. If the surfaces are not parallel, gaps may occur between the surfaces or between a surface and the viscous medium supposed to bind the surfaces together. Such gaps may decrease the stability of the mounting of the component, which may for example increase the risk of the component peeling off.

### SUMMARY

It is therefore an object of the present invention to overcome at least some of the above-mentioned drawbacks, and to provide an improved method for mounting a component on a workpiece and an improved system for depositing a viscous medium on a component and/or on a workpiece.

This and other objects are achieved by means of a method and a system as defined in the appended independent claims. Other embodiments are defined by the dependent claims.

According to a first aspect of the present disclosure, a method for mounting a component on a workpiece is provided. The method comprises obtaining information regarding a surface topography of at least one of a first surface of the component and a local surface of the workpiece onto which the component is to be mounted.

The method further comprises forming a plurality of deposits of a viscous medium on at least one of the first surface and the local surface. Each of the plurality of deposits has a height based on the obtained information. Each of the plurality of deposits is formed by applying at least one droplet of the viscous medium using non-contact dispensing.

The method further comprises placing the component on the workpiece, such that the plurality of deposits of viscous medium forms a connection between the component and the workpiece.

Placing the component on the substrate may include bringing the first surface and the local surface together, such that the plurality of deposits of viscous medium ensures (physical and/or electrical) contact between the component and the workpiece.

The local surface may be a portion of a mounting surface of the workpiece. A mounting surface of the workpiece may comprise one or more local surfaces, wherein each local surface may be adapted to receive a component.

The information regarding surface topography may comprise information about the shape of the first surface of the component and/or of the local surface of the workpiece. For example, it may comprise information about a deviation of the surface from a flat plane, such as a warpage or curvature of the first surface or the local surface. The information may also describe or indicate structures on the surface, such as bumps, ridges, valleys, or holes.

Obtaining and analyzing information regarding a surface topography of at least one of the first surface and the local surface may for example be performed by (or by the use of) a computing device, such as a processor, a control unit or a computer.

Forming deposits may for example be performed by (or by the use of) a depositing device, or non-contact dispensing device, for depositing/applying a viscous medium. Non-contact dispensing may include different methods for shooting (jetting, propelling) droplets of a viscous medium onto a substrate (surface). Such methods may provide one or more of: fast deposition of droplets, deposition of more than one droplet at a time, and deposition individually sized droplets.

A non-contact dispensing device performing the formation of deposits in the method of the first aspect of this disclosure may be in communicative contact with a computing device such as a processor, control unit or computer in which the obtaining information regarding surface topography is performed. Such a computing device may also be integrated in the non-contact dispensing device.

Placing the component on the workpiece, or bringing the first surface and the local surface together, may for example be performed by (or by the use of) a mounting machine, a pick-and-place machine, a die bonder, or a mounting robot.

Differences in the topography of the first surface and/or the local surface, due to e.g. warpage of the component or workpiece, may lead to a non-constant distance between the surfaces when mounting the component on the workpiece. In order for the deposits to form a connection between the component and the workpiece upon mounting of the workpiece, heights of the deposits may need to be adapted to the topography of one or both surfaces.

For example, in places (portions) in which the distance is larger than average, it may be necessary to apply more viscous medium to ensure that the viscous medium is in contact with both surfaces when the component is mounted. Forming larger (higher) deposits in portions in which the distance between the first surface of the component and the local surface of the workpiece is larger than an average distance between the surfaces may ensure connection between the component and the workpiece. Thus, the component may be more securely mounted.

The workpiece may for example comprise a board, such as a printed circuit board (PCB), a flexible PCB or a printed wiring board (PWB). Alternatively, the workpiece may be a substrate for ball grid arrays (BGA), a flexible substrate (e.g. paper or plastic), chip scale packages (CSP), quad flat packages (QFP), wafers, flip-chips, or the like. In some applications, the workpiece may be a material or surface which may receive viscous medium. The workpiece may be a flat surface or warped surface, but it is also envisioned that the substrate may form a three-dimensional surface and/or comprise irregular shapes and/or wells wherein the viscous medium is to be deposited.

The term ‘deposit’ may, in the context of the present disclosure, refer to the viscous material deposited onto the workpiece, for example in the form of a droplet or a dot.

The height of a deposit may be related to the volume of the deposit. A higher deposit may thus be formed by increasing the volume of the deposit. An increase in the deposit volume may generally result in an increase in the deposit height as well as the deposit footprint, i.e. the area on the workpiece or component that the deposit covers.

A deposit may be made higher (larger) by adding more viscous medium to an already existing deposit. Alternatively, a deposit with a larger volume may be formed initially. A smaller (less high) deposit may e.g. be formed by forming a deposit with a smaller volume. Alternatively, a deposit of standard (average) height may be formed, and then some of the viscous material of the deposit removed, e.g. by suction.

In the present disclosure, the phrase ‘based on’ in the context of determining the distances or heights (or control parameters controlling the heights) may comprise ‘determined as a function of’, ‘proportional’, ‘directly proportional’, and ‘derived from’.

According to some embodiments, obtaining information regarding a surface topography of at least one of the first surface of the component and the local surface of the workpiece may comprise performing surface measurements of at least one of the first surface and the local surface.

For example, the local surface of the workpiece may be scanned or otherwise measured. As another example, the entire mounting surface of the workpiece (comprising one or more local surfaces) may be scanned or otherwise measured. The first surface of the component may be scanned or otherwise measured. Different methods and devices for scanning and measuring surfaces are known in the art.

According to some embodiments, obtaining information regarding a surface topography of at least one of the first surface of the component and the local surface of the workpiece may comprise retrieving information of a surface topography of at least one of the first surface and the local surface from a storage unit.

Many manufacturers provide detailed topography data of the components they produce. The storage unit may for example comprise topography data provided by the component manufacturer. Alternatively, or additionally, the storage unit may comprise data from previous measurements made on the component and/or the workpiece.

The storage unit may for example be a server, a non-volatile storage medium, an internal memory etc.

According to some embodiments, the method may further comprise identifying, from the obtained surface topography information, at least one portion of the first surface or the local surface at which a distance between the first surface and the local surface, upon mounting of the component on the workpiece, will be larger than an average distance between the first surface and the local surface.

Further, forming a plurality of deposits may comprise forming at least one deposit in the at least one identified first portion having a height which is larger than an average height of the deposits within the plurality of deposits.

From (or based on) the obtained information, the average distance between the first surface and the local surface when the component is mounted on the workpiece may be calculated or estimated. A first portion (or a plurality of first portions) in which the distance between the first surface and the local surface will be larger than the average distance may further be identified.

It will be appreciated that in a situation wherein, for example, the distance between the first surface and the local surface is substantially the same apart from in one portion in which the distance is shorter, the average distance between the surfaces will be (slightly) lower than the median distance (which will be equal to the substantially same distance between the remainder of the surfaces). Forming a relatively smaller deposit in the one portion in which the distance is shorter will then result in the deposits in the other regions having a height which is (slightly) larger than the average height.

According to some embodiments, the method may further comprise identifying, from the obtained information, at least one second portion of the first surface or the local surface at which a distance between the first surface and the local surface, upon mounting of the component on the workpiece, will be smaller than the average distance between the first surface and the local surface. At least one deposit formed in the at least one second portion may have a height which is smaller than the average height of the plurality of deposits.

Some components and/or workpieces, especially ones having larger surface areas, may have a more pronounced warpage or several regions in which the surface topography differs from a plane. Identifying both first portions with larger distances and second portions with smaller distances may provide that larger deviations in the distance may be compensated by altering the deposit heights.

According to some embodiments, the method may further comprise, for a plurality of positions at which deposits are to be formed, analyzing a predicted distance between the first surface and the local surface, which is to be formed upon mounting of the component on the workpiece, based on the information regarding a surface topography. The method may further comprise, for each deposit which is to be formed in one of the plurality of positions, calculating a compensation factor based on the analysis of the distance. Forming a plurality of deposits may further comprise adapting a height of each deposit being formed in one of the plurality of positions based on its compensation factor.

The compensation factor may determine a quantity or factor by which the deposit volume or height is to differ from the average volume/height of the plurality of deposits. Alternatively, the compensation factor may determine a quantity or factor by which the deposit volume or height is to differ from a standard or nominal deposition volume or height.

The compensation factor for each deposit may be determined to compensate for differences in the distance between the first surface and the local surface at the position of each deposit.

It is appreciated that the step of analyzing a distance between the first surface and the second surface may comprise identifying at least a first portion in which the distance is larger than an average distance between the surfaces and/or at least a second portion in which the distance is smaller than an average distance between the surfaces.

According to some embodiments, forming a plurality of deposits may be followed by applying further viscous medium to at least one of the plurality of deposits using non-contact dispensing.

A deposit may, for example, be built (formed) by repeated application of droplets of a similar or different size/volume.

For example, a plurality of deposits all having substantially the same height may first be formed. Then, additional viscous medium may be added to deposits for which a larger height is required.

As an alternative, an initial set of deposits (e.g. of similar size/volume/height) may already be formed on the first surface or the local surface. The plurality of deposits may then be formed on top of at least some of the initial set of deposits by applying at least one droplet of the viscous medium using non-contact dispensing.

For example, applying further viscous medium to at least one of the plurality of deposits, may result in at least one deposit having a height which is larger than an average height of the plurality of deposits.

Given enough time, a quantity of viscous material on a surface, such as a deposit, may deform to optimize its surface energy. This effect may lead to a flattening and spreading out of droplets of viscous media on a surface. A larger volume deposit may lead to a larger footprint if the deposit spreads out. However, when working in shorter timespans, it may be possible to form two or more deposits on top of one another, without the deposits spreading out/flattening.

Forming so called ‘double-deposits’, i.e. depositing additional material on an already formed deposit, may increase the height of a deposit without increasing the width/foot print as much as when forming a single deposit with a larger volume. Thus, the risk for (e.g. solder) bridging between two deposits may be decreased.

In embodiments in which a plurality of deposits is formed and height adaptations made afterwards, a smaller (less high) deposit may be formed by removing (e.g. by suction) a deposit and forming a smaller deposit (with a smaller volume) in the same place. Alternatively, the height of a deposit may be decreased by removing some of the material of the deposit.

According to some embodiments, obtaining information comprises, while forming the plurality of deposits, performing measurements of the at least one of the first surface and the local surface on which the plurality of deposits are formed.

In other words, the measurements of the surface may be performed at the same time as, or during, the formation of the plurality of droplets.

For example, a plurality of deposits may be formed based on initial information received from earlier measurements or stored values. While forming the plurality deposits, or before or after forming the deposits, complementary measurements of the surface may be made. For example, measurements may be made at positions, or close to positions, at which deposits are made. Further viscous medium may, if necessary, be added to one or more deposits based, at least in part, on the complementary measurements.

Alternatively, a plurality of deposits having e.g. standard heights may be formed at the same time as first measurements are made.

Many methods of non-contact dispensing involve a dispensing device (e.g. nozzle, head, etc.) scanning, flying over or sweeping the surface on which deposits are formed, such that all relevant parts of the surface can be accessed/addressed by the dispensing device. Alternatively, a holder holding the e.g. workpiece or component may move relative to the dispensing device. A measurement device may be arranged to also access relevant parts of the surface during formation (application) of the deposits.

According to some embodiments, the method may further comprise, after placing the component on the workpiece, applying energy to the deposits, component, and/or the workpiece, to process the deposits. The information regarding a surface topography may comprise information regarding a predicted change in topography of at least one of the first surface and the local surface resulting from the application of energy.

Processing the deposits by application of energy to the deposits, component, and/or the workpiece may alter one or more properties of the viscous medium. Depending on the material, the viscosity of the viscous medium may for example decrease (melt, reflow) or increase (harden) as a reaction to the applied energy, which may in turn lead to more robust joints between the component and the workpiece.

For example, the method may comprise a reflow step, in which the workpiece and the component are subjected to energy in the form of controlled heat. This may (partially) melt the deposits, which may harden upon cooling to form permanent joints. Reflow may for example be used when the viscous medium comprises a solder paste.

Exposure to heat may induce further changes in the topography of the workpiece and/or the component. These changes in topography often follow similar patterns, such that the resulting topography change can, at least approximately, be predicted. The predictions may for example be based on prior knowledge, testing, measurements, information from a producer etc. Using these predictions as part of the obtained topography information, based on which heights of one or more deposits may be determined, may allow for adapting deposit sizes to compensate these changes.

For example, the application of energy may include application of radiation, such as visible light, UV light or IR radiation, to the deposits. Treating/or processing the deposits using radiation may cure/harden the deposits.

Alternatively, energy may be applied in the form of sound or vibrations.

Application of energy may be selective to the deposits, e.g. by using a laser or other form focused energy transmitter aimed directly at the deposits. In such embodiments, energy such as heat may spread from the deposits to the workpiece and/or component to induce further warpage. Alternatively, application of energy may be broader, and e.g. aimed at the component or the workpiece, or to the assembly formed by the component mounted on the workpiece.

According to some embodiments, the non-contact dispensing may include jet printing or laser induced forward transfer (LIFT).

Jet printing, or jetting, relates to non-contact generation of a droplet/volume of a viscous medium. An impulse is applied to the viscous medium, thereby generating a momentum which causes a droplet to break off from the main volume of viscous medium and be ejected through a nozzle (onto a substrate). The droplet formation is therefore controlled by inertial forces and/or surface tension. The nozzle may glide over the surface of the substrate and shoot droplets of solder paste onto the surface. In order to jet more than one droplet at a time, more than one nozzle can be used.

Laser induced forward transfer (LIFT) is a non-contact, nozzle-free, dispensing method that allows deposition of small volumes of viscous medium from a donor film/substrate onto a receiving substrate using a pulsed laser beam. By tuning the laser parameters, the volume of the propelled droplets can be adapted. When using multiple laser beams, LIFT enables the deposition of multiple droplets/deposits, each having an individual volume, at the same time or independently of each other.

Many different types of components may be mounted onto different types of workpieces using methods described herein. The method may specifically apply to components having more than one point of contact to be connected with the workpiece. According to some embodiments, the component may be an electrical component.

The component may be any electrical component having more than one connection point. The component may for example be a multiple input/output (I/O) electrical package.

According to some embodiment, the viscous medium may comprise an electrically conductive material.

Especially in embodiments wherein the component is an electrical component, a viscous medium comprising an electrically conductive material may ensure not only an adhesive or physical/mechanical connection between the component and the workpiece, but also an electrical connection. Thus, in such embodiments, at least some deposits may act as electrical conductors allowing electrical signals to pass between the component and the workpiece.

For example, the viscous medium may comprise solder paste, electrically conductive glue or another electrically conductive material.

According to some embodiments, the component may comprise receptors and/or transmitters for optical signals and the workpiece may comprise corresponding receptors and/or transmitters for optical signals adapted for communication with the component. In such embodiments, the deposits of viscous material may, when the component is mounted on the workpiece, form communication channels, such as waveguides, allowing for optical signals to pass between the component and the workpiece.

The method in accordance with the first aspect of the present disclosure may further be used when a second component is to be mounted onto a second local surface of the workpiece. The surface topography of the second component may be different from that of the (first) component. Further, the surface topography of the second local surface may be different from that of the (first) local surface.

The method may thus further comprise obtaining further information regarding a surface topography of at least one of a first surface of the second component, and a second local surface of the workpiece onto which the second component is to be mounted.

The method may further comprise forming a second plurality of deposits of a viscous medium on at least one of the first surface of the second component and the second local surface. Each of the second plurality of deposits has a height based on the obtained further information. Each of the second plurality of deposits is formed by applying at least one droplet of the viscous medium using non-contact dispensing.

The method may further comprise placing the second component on the workpiece, such that the second plurality of deposits of viscous medium forms a connection between the second component and the workpiece.

The method may further comprise identifying, from the further information, at least one further first portion of the first surface of the second component or the second local surface at which a distance between the first surface of the second component and the second local surface, upon mounting of the second component on the workpiece, will be larger than an average distance between the first surface of the second component and the second local surface.

The method may further comprise forming a second plurality of deposits of a viscous medium on at least one of the first surface of the second component and the second local surface, wherein at least one deposit formed in the at least one further first portion has a height which is larger than an average height of the second plurality of deposits, and placing the second component on the workpiece, such that the second plurality of deposits of viscous medium forms a connection between the second component and the workpiece.

According to a second aspect of the present disclosure, a system for depositing a viscous medium is provided. The (depositing) system comprises a non-contact dispensing device which is arranged for applying droplets of a viscous medium onto a first surface of a component to be mounted on a workpiece and/or a local surface of the workpiece onto which the component is to be mounted.

The system further comprises a control unit, which is adapted to obtain information regarding a surface topography of at least one of the first surface and the local surface of the workpiece.

The control unit is further adapted/configured to determine, based on the obtained information, heights of a plurality of deposits of a viscous medium that is to be formed on at least one of the first surface and the local surface, such that the plurality of deposits forms a connection between the component and the workpiece upon placing the component on the workpiece.

The control unit is further configured to cause the non-contact dispensing device to form each of the plurality of deposits of the viscous medium on the first surface or the local surface by applying at least one droplet of the viscous medium using non-contact dispensing.

For example, the control unit may send operational requests to the depositing device, instructing the depositing device to form the deposits.

The control unit may be an integrated part of the depositing device. The control unit may be external to the depositing device and arranged to communicate with the depositing device. The control unit may comprise a sub-unit internal to the depositing device and a sub-unit external to the depositing device. The control unit may further be configured to control operation of the depositing device.

According to some embodiments, the control unit of the system may be in communicative contact with a storage unit. The storage unit may comprise information regarding a surface topography of at least one of the first surface of the component and the local surface of the workpiece.

According to some embodiments, the control unit may further be adapted/configured to identify, from the obtained information, at least one first portion of the first surface of the local surface at which a distance between the first surface and the local surface, upon mounting of the component on the workpiece, will be larger than an average distance between the first surface and the local surface. The control unit may further be configured to determine the heights of the deposits such that at least one deposit to be formed in the at least one identified first portion has a height which is larger than an average height of the plurality of deposits.

Many types of devices for depositing viscous media are known in the art.

According to some embodiments, the non-contact dispensing device may be selected from a jet printing device and a laser induced forward transfer (LIFT) device.

For example, a jet printing (jetting) device may comprise an ejector for jetting droplets of the viscous medium onto the first surface or the local surface, thereby depositing the viscous medium on the surface in question. Such an ejector generally comprises a chamber for accommodating a volume of the viscous medium prior to the jetting thereof, a jetting nozzle communicating with the nozzle space, and an impacting device for impacting and jetting the viscous medium from the chamber through the nozzle in the form of droplets. Further, a feeder may be utilized to feed the medium into the nozzle space. The amount, or volume, of the deposited viscous medium at different locations on the substrate may be varied by applying several droplets on top of each other, thus forming a larger deposit, or by varying the volume of the jetted droplet by e.g. feeding a larger or smaller volume of the viscous medium into the chamber.

The non-contact dispensing device may use a method where one deposit is created at a time or a method where several deposits are created at the same time or a combination of the two in a parallel event or in a series of events.

For example, the system may be adapted to receive a workpiece or substrate on which an initial plurality of deposits has already been formed, e.g. using a screen-printing (or stencil-printing) method. The non-contact dispensing device may be configured to add further viscous medium to at least one deposit. The system may further be adapted to remove a deposit and place a smaller deposit in its place. As an alternative, the system may comprise more than one depositing device, wherein a first depositing device forms a plurality of deposits, and a second depositing device alters the height/volume of one or more of the already formed deposits.

According to some embodiments, the system may further comprise a surface measurement device configured to perform measurements of at least one of the first surface and the local surface.

The surface measurement device may use one or more of many known scanning, distance and surface measurement techniques known in the art. For example, the surface measurement device may include a distance measurement device, e.g. a LIDAR, to make measurements of the surface.

According to some embodiments, the surface measurement device may be arranged to perform measurements of the at least one of the first surface and the local surface while the non-contact dispensing device applies droplets of the viscous medium onto the at least one of the mounting surface and the local surface.

According to a third aspect of the present disclosure, a storage medium comprising instructions is provided. The instructions, when being carried out by a control unit of a system for depositing a viscous medium, will bring the control unit to obtain information regarding a surface topography of at least one of a first surface of a component and a local surface of a workpiece onto which the component is to be mounted.

The instructions will further, when being carried out by the control unit of the depositing system, bring the control unit to determine, based on the obtained information, heights of a plurality of deposits of a viscous medium that is to be deposited on at least one of the first surface and the local surface, such that the plurality of deposits forms a connection between the component and the workpiece upon placing the component on the workpiece.

Further, when being carried out by the control unit of the depositing system, the instructions will bring the depositing device to form the plurality of deposits of a viscous medium on at least one of the first surface and the local surface, by applying at least one droplet of the viscous medium using non-contact dispensing.

According to some embodiments, the instructions may further, when being carried out by the control unit of the depositing system, bring the control unit of the depositing system to identify, from the obtained information, at least one portion of the first surface or the local surface at which a distance between the first surface and the local surface, upon mounting of the component on the workpiece, will be larger than an average distance between the first surface and the local surface. The instructions may further bring the control unit to determine the heights such that at least one deposit in the identified portion has a height which is larger than an average height of the plurality of deposits.

It is noted that other embodiments using all possible combinations of features recited in the above described embodiments may be envisaged. Thus, the present disclosure also relates to all possible combinations of features mentioned herein. Specifically, features explained in more detail with reference to an aspect of the present disclosure may apply to corresponding features of another aspect of the present disclosure. For example, the system may be adapted to perform method steps described with reference to the first aspect of the disclosure. Further, the storage medium of the third aspect may comprise instructions which may bring a system of the second aspect to perform method steps of the first aspect of the disclosure.

### BRIEF DESCRIPTION OF DRAWINGS

Exemplifying embodiments will now be described in more detail, with reference to the following appended drawings:

FIG. 1 is an illustration of a component and a workpiece, in accordance with some embodiments;

FIG. 2 is a cross-section of a component and a local surface of a workpiece, in accordance with some embodiments;

FIG. 3 is an illustration of a local surface of a workpiece on which a plurality of deposits has been formed, in accordance with some embodiments;

FIG. 4 is a cross-section of a component and a local surface of a workpiece, in accordance with some embodiments;

FIG. 5 is an illustration of a local surface of a workpiece on which a plurality of deposits has been formed, in accordance with some embodiments;

FIGS. 6a-c are illustrations of a component mounted on a local surface of a workpiece, in accordance with some embodiments;

FIG. 7 is a further illustration of a component mounted on a local surface of a workpiece, in accordance with some embodiments;

FIG. 8 is a schematic illustration of a system for depositing a viscous medium, in accordance with some embodiments;

FIG. 9 is a schematic illustration of a system for depositing a viscous medium, in accordance with some embodiments.

As illustrated in the figures, the sizes of the elements and regions may be exaggerated for illustrative purposes and, thus, are provided to illustrate the general structures of the embodiments. Like reference numerals refer to like elements throughout.

### DETAILED DESCRIPTION

Exemplifying embodiments will now be described more fully hereinafter with reference to the accompanying drawings in which currently preferred embodiments are shown. The invention may, however, be embodied in many different forms and should not be construed as limited to the embodiments set forth herein; rather, these embodiments are provided for thoroughness and completeness, and fully convey the scope of the invention to the skilled person.

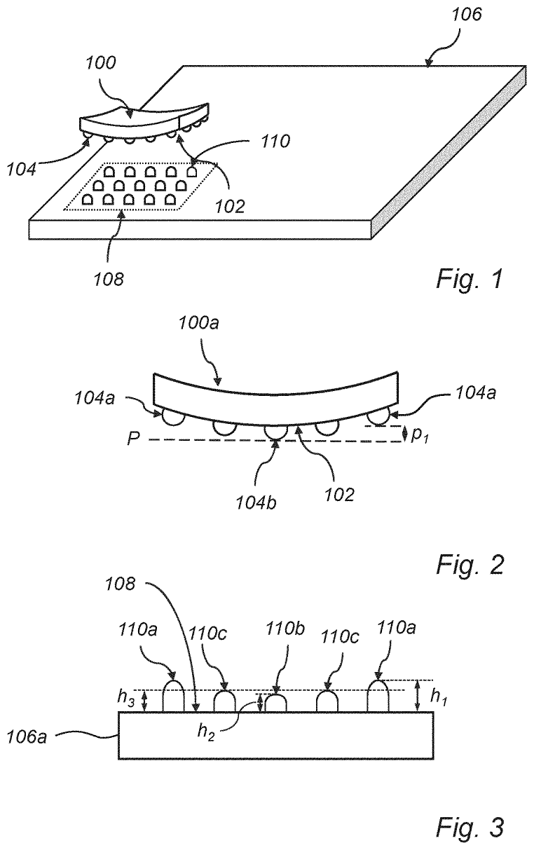

With reference to FIG. 1, a component 100 and a workpiece 106, in accordance with some embodiments, will be described.

FIG. 1 shows a component 100 about to be mounted on a local surface 108 of a workpiece 106. The component 100 has a first surface 102 comprising a plurality of contact pads 104. The contact pads 104 are arranged in a grid pattern on the first surface 102, although not all pads 104 are visible in FIG. 1. For example, the component 100 may comprise a ball grid array (BGA).

The component 100 is warped such that the corners of the component 100 are slightly curved away from the workpiece 106. This warpage has been exaggerated for illustrative purposes.

On the workpiece 106, a plurality of deposits 110 of a viscous medium has been formed on the local surface 108. These deposits 110 are formed in positions matching the positions of the contact pads 104 of the component 100. When the component 100 is mounted on the local surface 108 of the workpiece 106, the deposits 110 line up with the contact pads 104. After mounting, the viscous medium of the deposits 110 holds the component 100 in place. However, as the component 100 is warped, the first surface 102 is not parallel with the local surface 108. The deposits 110 depicted in FIG. 1 are all of the same height, thus, since the distance between the first surface 102 of the component 100 and the local surface 108 of the workpiece 106 varies, not all deposits 110 may reach its corresponding contact pad 104. Gaps may therefore be formed between a deposit 110 and its corresponding contact pad 104, which may result in the component 100 not being properly held in place. In embodiments in which the component 100 is electric or optical, the deposits 110 of viscous medium may have the purpose of conveying electrical or optical signals between the component 100 and the workpiece 106. In such embodiments, a gap between the deposit 110 and the contact pad 104 or contact point may lead to functionality issues.

It will be appreciated that not all components have contact pads 104 extending from the first surface 102 as illustrated in FIG. 1. Some components have other types of contact points, and other components may not have specific contact points at all.

Further, in FIG. 1 and some following examples, only the component 100 is curved/warped. It will, however, be appreciated that the workpiece 106 and specifically the local surface 108 thereof, may also be warped. In some situations, both the component and the workpiece may be warped/curved, and in other situations only the component or only the workpiece may be warped. Further, the first surface of the component and/or local surface of the workpiece may comprise structures including for example holes, ridges, bumps or valleys.

With reference to FIGS. 2 and 3, analysis of the topography of the first surface 102 of the component 100a, and formation of deposits 110a-c on the workpiece 106, in accordance with some embodiments, will be described.

FIG. 2 is an illustration of a component 100a. The component 100a of FIG. 2 may be equivalent to the component 100 described above with reference to FIG. 1. FIG. 3 is an illustration of a section of a workpiece 106 comprising the local surface 108. A plurality of deposits 110a-c of a viscous medium has been formed on the local surface 108.

In the example illustrated in FIG. 2, the first surface 102 is curved, information regarding the topography of the first surface 102 may thus comprise information about the curvature of the first surface 102. The local surface 108 of the workpiece 106 in FIG. 3 is flat (not warped), information regarding the topography of the local surface 108 may thus comprise information that the local surface 108 is flat.

The information regarding the topography of the first surface 102 may further comprise information about the contact pads 104, 104a and their positions. The information regarding the topography of the first surface 102 may for example describe how the first surface differs from a plane P. The information may include a topography map, or measurements of specific positions.

In FIG. 3, a plurality of deposits 110a-c have been formed on the local surface 108 by application of droplets of viscous medium using non-contact dispensing. The deposits are formed in positions which are to be aligned with the contact pads 104 when the component 100a is mounted on the workpiece 106. Each of the deposits 110a-c has a height h₁, h₂, h₃ which is based on the information regarding the surface topography of the first surface 102. In some embodiments, the heights of the deposits may be based on surface topographies of both the first surface 102 and the local surface 108. In other embodiments, one of the surfaces may be assumed to be flat (planar/non-curved).

In FIG. 2, the plane P extends from the lowest point of the middle contact pad 104b. Due to the warpage of the component 100a, the outermost contact pads 104a are separated a distance p₁ from the plane P. The height h₁ of the deposits 110a which are positioned to align with the outermost contact pads 104a must therefore be higher than the height h₂ of the center deposit 110b in order to be in contact with contact pad 104a upon mounting of the component 100a on the workpiece 106. In the present example, the center deposit 110b may have been formed by application at least one droplet of the viscous medium using non-contact dispensing. The center deposit 110b may for example have a standard height/volume, or a minimal accepted height/volume. Each of the other deposits 110a, 110c may have been formed by non-contact dispensing of a single droplet having a larger volume adapted to provide a height such that the resulting deposit forms a connection between the workpiece and the respective contact pad. Alternatively, each of the other deposits 110a, 110c may have been formed by non-contact dispensing of more than one droplet, such that the resulting deposit forms a connection between the workpiece and the respective contact pad.

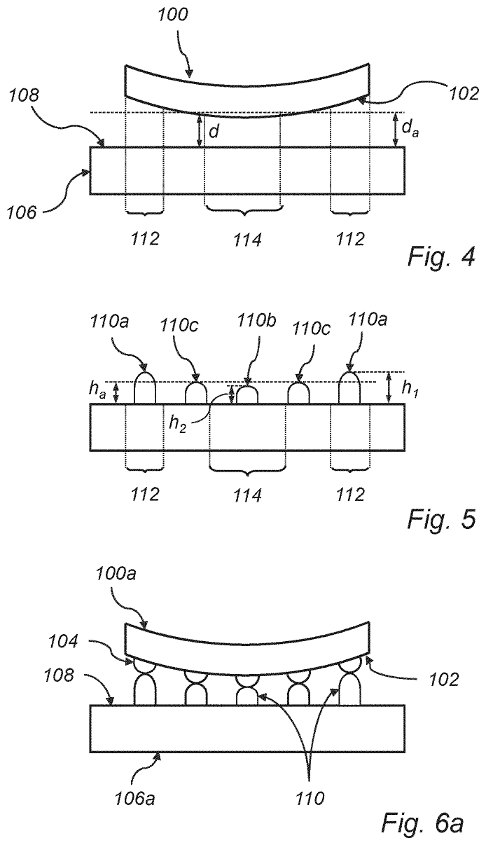

With reference to FIG. 4, identification of first portions 112 and second portions 114, in accordance with some embodiments, will be described. With reference to FIG. 5, formation of deposits 110a-c on the workpiece 106, in accordance with some embodiments, will be described.

FIG. 4 is an illustration of a component 100 and a section of a workpiece 106 comprising the local surface 108 onto which the component 100 is to be mounted. The component 100 and the workpiece 106 of FIG. 4 may be equivalent to the component 100, 100a and the workpiece 106, 106a described above with reference to FIGS. 1-3, except in that in this example there are no contact pads 104 on the first surface 102 of the component 100a. It will however be appreciated that the methods described with reference to FIGS. 4 and 5 are applicable for components including contact pads (or other structures) as well.

FIG. 5 is an illustration of a section of a workpiece 106 comprising the local surface 108. A plurality of deposits 110a-c of a viscous medium has been formed on the local surface 108.

As in FIGS. 2 and 3, the first surface 102 is curved and the local surface 108 of the workpiece 106 is flat (not warped). When data regarding the surfaces 102, 108 have been obtained, it is possible to predict and analyze a future distance variation between the first surface 102 and the local surface 108 when the component 100 is mounted on the workpiece 106.

The distance d between the first surface 102 and the local surface 108 varies in FIG. 2. Two first portions 112 have been identified in which the distance is larger than the average distance dₐ. A second portion 114 has also been identified, in which the distance is smaller than the average distance dₐ.

In the example illustrated in FIG. 5, a plurality of deposits 110a-c have been formed on the local surface 108. The heights of all deposits 110a-c are not equal. In particular, the deposits 110a formed in the first regions 112 have a height h₁ which is larger than the average height hₐ of the deposits 110a-c. the deposit 110b which is formed in the second region 114 has a height h₂ which is smaller than the average height hₐ of the deposits 110a-c. The remaining two deposits 110c, which are formed outside of the first regions 112 and the second region 114, have heights coinciding with the average height hₐ of the deposits.

The analysis of the distance may be performed in different ways. As an example, the average distance dₐ may be calculated. After this, first portions 112 in which the distance is larger than the average distance dₐ may be identified, and (optionally) second portions 114 in which the distance is smaller than the average distance dₐ may be identified. Based on this, the step of forming the deposits may be adapted such that (at least some) deposits 110a in the first regions 112 have a height h₁ which is larger than an average height hₐ of the plurality of deposits 110a-c. Further, (optionally) at least some deposits 110c formed in second portions 114 may have a height h₂ which is smaller than the average height hₐ of the deposits 110a-c.

Often, the positions of the deposits are predetermined to match contact points of the component 100 and/or the workpiece 106. Thus, as a further example, the distance d at each predetermined position of a deposit (or at least a subset of the predetermined positions of a deposit) may be analyzed. From this analysis, regions 112, 114 in which the distance is larger or smaller than an average may be determined, and the heights of the deposits adapted accordingly. Alternatively, a compensation factor may be calculated for each analyzed position (in other words for each deposit in an analyzed position) based on the analysis of the distance at the position. Thus, each deposit in an analyzed position may receive a height adapted to the specific distance in that position. If both surfaces 102, 108 were perfectly flat, the compensation factor for each analyzed deposit would be 1, since all the deposits would have the same size, and a nominal volume or an initial estimate of volume (and height) based e.g. on the size of the contact points/pad or the distance in between the contact points may be used.

Information regarding the surface topography of the surfaces 102, 108 may not only comprise information about the current topography of the surfaces. As previously mentioned, the analyzed distance is the distance between the first surface 102 and the local surface 108 upon mounting of the component 100 on the workpiece 106. In certain embodiments, mounting the component may comprise applying energy, for example heat or radiation (such as light), directly to the deposits or to the component and the workpiece, in order to further secure the component in place. Depending on the viscous medium used, light may for example be applied to the deposits in order to cure (harden) the deposits, or heat may be applied to melt/reflow the viscous material of the deposits. The application of energy may induce a further deformation of the component 100, 100a and/or the workpiece 106. This further deformation caused by the energy application often follows certain patterns, meaning that the further deformation may be predicted. The information regarding the surface topography of the surfaces 102, 108 may further comprise information regarding the predicted topography change, so that the heights of the deposits 110a-c may be adapted to compensate the predicted topography change.

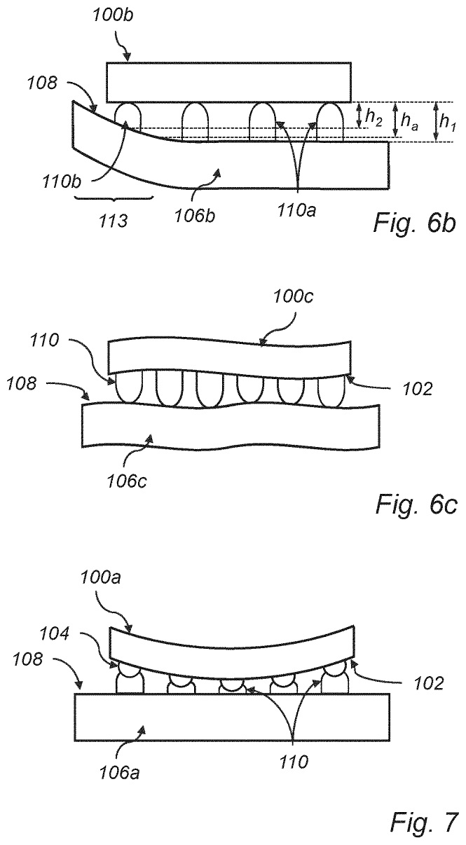

With reference to FIGS. 6a-c, mounting of a component 100a-c onto a local surface 108 of a workpiece 106a-c will be described.

FIGS. 6a-c are illustrations of a component 100a-c mounted on a local surface 108 of a workpiece 106a-c.

The component 100a and the workpiece 106a of FIG. 6a may be equivalent to the components 100, 100a and workpieces 106 described above with references to the preceding figures.

The component 100a has a plurality of contact pads 104 on its first surface 102, like in FIGS. 1 and 2. A plurality of deposits 110 have been formed on the local surface 108 in positions aligned with the positions of the contact pads 104. Like in FIGS. 3 and 5, the heights of the deposits 110 have been adapted based on the surface topographies of the first surface and the second surface, and/or on the variations in distance between the first surface 102 and the local surface 108 caused by the warpage/curvature of the component 100a. Each deposit 110 thus forms a connection (ensures contact) between the workpiece 106 and its respective contact pad 104.

Placing the component on the workpiece, or mounting the component 100a onto the workpiece, may comprise bringing the component 100a and the workpiece 106c together, and aligning the first surface 102 with the local surface 108. Thus, each contact pads 104 may be aligned with a corresponding deposit 110. The viscous medium of the deposits 110 may keep the component 100 in place.

FIG. 6b illustrates a component 100b mounted on a local surface 108 of a workpiece 106b. The example shown in FIG. 6b may be equivalent to the example shown in FIG. 6a, except in that the component 100b is not warped/curved while the workpiece 106b is warped/curved, and that the component 100b has no contact pads.

More specifically, the workpiece 106b is curved such that an end portion 113 of the local surface 108 is curved towards the component 100b. Thus, the distance between the component 100b and the workpiece 106b is smaller in the end portion 113, while the distance is substantially the same for the rest of the local surface 108. The deposit 110b formed in the end portion 113 has a height h₂ based on the topography of the first surface and the local surface 108. The height h₂ of the deposit 110b formed in the end portion 113 is therefore lower than the height h₁ of the other deposits 110a. The height h₂ is smaller than the average height hₐ, while the other deposits 110a have the same height h₁ which is larger than the average height hₐ.

FIG. 6c illustrates a warped/curved component 100c mounted on a local surface 108 of a curved/warped workpiece 106c. A plurality of deposits 110 has been formed on the first surface 102 of the component 100c before mounting of the component 100c on the workpiece 106c. Each of the deposits 110 has an individual height based on (adapted to) the topographies of the first surface and the local surface and/or based on the distance between the first surface 102 and the local surface 108 at the position at which the individual deposit is formed.

In other embodiments, deposits may be formed on both the first surface and the local surface before mounting. The deposits may be formed in corresponding positions on the surfaces, such that they line up upon mounting of the component on the workpiece. Alternatively, the deposits may be formed in complementary positions.

With reference to FIG. 7, further steps of mounting a component 100 on a workpiece 100 will be described.

FIG. 7 shows the same example as illustrated in FIG. 6a, except in this figure, the contact pads 104 have partially sunk into the deposits 110. The viscous material of the deposits 110 may allow that the deposits 110 become deformed after initial placement/mounting of the component 100a. For example, the deformation may take place due to gravity acting on the component 100a, or to an external force applied on the component 100a and/or the workpiece 106a during mounting of the component 100a. In some embodiments, after bringing the component 100a and the workpiece 106a together to form an assembly, heat, light, or other form of energy may be applied to the assembly (comprising the component 100a and the workpiece 106a).

In some embodiments, a controlled application of heat may cause the deposits 110 to reflow, or melt. Such a decrease in viscosity (caused by the application of heat) may allow a larger contact surface between the deposits and the contact pads 104 or points on the component 100a and the workpiece 106a. This decrease in viscosity may for example cause partial sinking of the contact pads into the deposits, as shown in FIG. 7. When the viscous material cools, it may harden to form more robust joints.

For example, in embodiments comprising electronic components and in which the viscous medium comprises solder paste, a controlled application of heat, light or other form of energy may cause the solder paste to reflow and form permanent solder joints

Alternatively, a controlled application of light or other form of energy may be performed to cure (harden) the viscous material of the deposits 110, thereby securing the component 100, 100a to the workpiece 106.

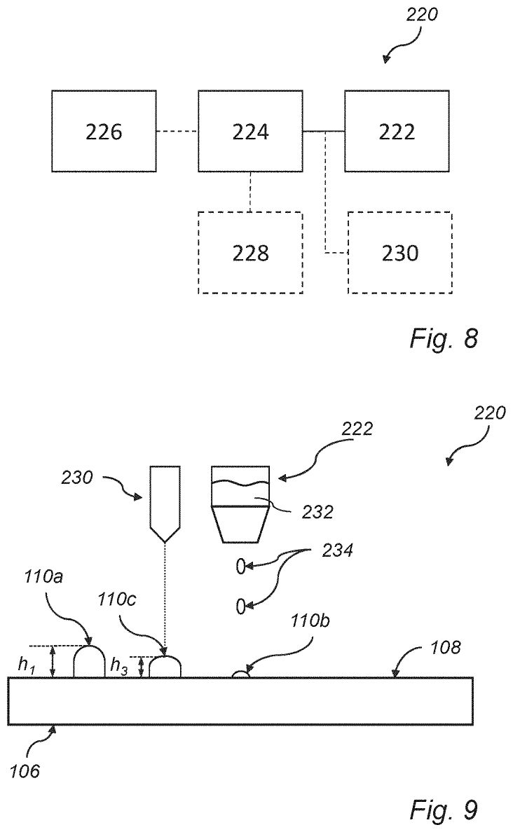

With reference to FIGS. 8 and 9, a system 220, in accordance with some embodiments, will be described.

FIG. 8 is a block diagram of a (depositing) system 220 for depositing a viscous medium. The depositing system 220 comprises a non-contact dispensing (depositing) device 222, which is arranged for depositing a viscous medium onto a surface, such as a first surface 102 of a component 100 or a local surface 108 of a workpiece 106, as described above with reference to FIGS. 1-7.

FIG. 9 is a schematic illustration of parts of a system 220 for depositing a viscous medium, illustrated during the deposition of a viscous medium onto a workpiece 106.

The depositing system further comprises a control unit 224. The control unit 224 may be internal to the non-contact dispensing 220. In other embodiments, the control unit 224 may be an external control unit, such as a processor, computer etc., in communicative contact with the non-contact dispensing 220.

The control unit 224 is configured to obtain information about surface topographies of a first surface of a component to be mounted on the workpiece and/or a local surface of the workpiece 106 on which the component is to be mounted. This information may for example be retrieved from a storage unit 226 in communicative contact with the control unit 224.

Alternatively, the depositing system may be configured to perform measurements of the first and/or local surface using measurement device 230.

The control unit 224 may further be adapted to use the obtained information to analyze how the surface topographies will affect the distance between the first surface of the component and the local surface of the workpiece 106. For example, this analysis may be performed as described above with reference to the preceding figures.

For example, the control unit 224 may be adapted to identify at least one first portion (such as first portion 112 in FIGS. 4 and 5) of the first or local surface in which the distance between these surfaces upon mounting will be larger than an average distance between the first surface and the local surface.

The control unit 224 is further adapted to determine heights of the deposits 110 to be formed on the workpiece 106 based on the information regarding surface topography. Heights of the deposits may be adapted to the predicted distance between the first surface and the local surface upon mounting. A deposit formed in a first portion, where the distance will be larger than the average distance, may thus have a height/volume larger than an average height/volume of the plurality of deposits.

The control unit 224 is further configured to cause the non-contact dispensing device 222 to form each of the deposits of viscous medium by applying ay least one droplet of the viscous medium onto the local surface of the workpiece 110 or the first surface of the component, using non-contact dispensing. For example, the control unit may send instructions to a non-contact dispensing device controller (not depicted) which may control operation of the non-contact dispensing device 222. Alternatively, the control unit 224 may directly control operation of the non-contact dispensing device 222. The system 220 may comprise a second depositing device 228. The second depositing device may be configured to deposit a plurality of deposits of medium of a substantially same height viscous onto a first surface of a component or a local surface of a workpiece. The non-contact dispensing 222 may then be configured to adapt a height of at least one of the plurality of deposits, e.g. by applying additional viscous medium to a deposit and/or by removing viscous medium from a deposit.

FIG. 9 shows an example of a non-contact dispensing device 222 arranged for applying droplets 234 of a viscous medium 232 onto a local surface 108 of a workpiece 106. The workpiece 106 may be equivalent to the workpiece 106a, illustrated in FIGS. 3, 5 and 6, adapted to receive the curved component 100a.

In the illustrated example, the non-contact dispensing device 222 is a jetting device, illustrated by a jetting nozzle comprising a volume of viscous medium 232. The jetting device 222 is shooting (jetting) individual droplets 234 onto the local surface 108 to build a deposit 110b. In this example, a plurality of droplets is applied to form the deposit 110b. In other embodiments, the size/volume of each individual jetted droplet may be adapted such that only one droplet is used to form each deposit 110a-c.

The jetting head has, prior to the illustrated moment, travelled over the workpiece 106, and formed a first deposit 110a having a first height h₁, and a second deposit 110c having a second lower height h₃.

The system 220 further comprises a measurement device 230, which is arranged and configured to perform measurements of the local surface 108. For example, the measurement device 230 may travel, e.g. together with the jetting head 222, over the local surface 108, performing measurements of the surface. In the illustrated example, the measurement device 230 is measuring a distance to the second deposit 110c. Repeated measurements may be used to determine a (new, updated) surface topography of the surface, and/or to measure the actual heights of the deposits 110a, 110c. Based on measurements made by the measurement device 230, further viscous medium may be applied, by the non-contact dispensing device 222, to one or more deposits 110a-c.

The person skilled in the art realizes that the present invention by no means is limited to the preferred embodiments described above. On the contrary, many modifications and variations are possible within the scope of the appended claims.

For example, the plurality of deposits may be formed on both the first surface of the component and on the local surface of the workpiece.

Although features and elements are described above in particular combinations, each feature or element can be used alone without the other features and elements or in various combinations with or without other features and elements.

Additionally, variations to the disclosed embodiments can be understood and effected by the skilled person in practicing the claimed invention, from a study of the drawings, the disclosure, and the appended claims. In the claims, the word “comprising” does not exclude other elements, and the indefinite article “a” or “an” does not exclude a plurality. The mere fact that certain features are recited in mutually different dependent claims does not indicate that a combination of these features cannot be used to advantage.

1. A method for mounting a component on a workpiece, the method comprising:
obtaining information regarding a surface topography of a first surface of said component and a local surface of said workpiece onto which said component is to be mounted;
forming a plurality of deposits of a viscous medium on at least one of said first surface and said local surface, wherein each of the plurality of deposits has a height based on the obtained information, and is formed by applying at least one droplet of the viscous medium using non-contact dispensing; and
placing the component on the substrate, such that said plurality of deposits of viscous medium forms a connection between said component and said workpiece.

2. The method of claim 1, wherein said obtaining information comprises performing surface measurements on at least one of said first surface and said local surface.

3. The method of claim 1, wherein said obtaining information comprises retrieving information of a surface topography of at least one of said first surface and said local surface from a storage unit.

4. The method of claim 1, wherein the forming of the plurality of deposits is followed by
applying further viscous medium to at least one of said plurality of deposits using non-contact dispensing.

5. The method of claim 4, wherein said obtaining information comprises, while forming the plurality of deposits, performing measurements of the at least one of the first surface and the local surface on which said plurality of deposits are formed.

6. The method of claim 1, further comprising:
after placing said component on the workpiece, applying energy to the deposits, component and/or the workpiece to process said deposits; wherein
said information regarding a surface topography comprises information regarding a predicted change in topography of at least one of said first surface and said local surface resulting from the application of energy.

7. The method of claim 1, wherein said non-contact dispensing includes jet printing or laser induced forward transfer, LIFT.

8. The method of claim 1, wherein said component is an electrical component.

9. The method of claim 8, wherein said viscous medium comprises an electrically conductive material.

10. A system for depositing a viscous medium, said system comprising:
a non-contact dispensing device arranged for applying droplets of a viscous medium onto a first surface of a component to be mounted on a workpiece or a local surface (108) of said workpiece onto which said component is to be mounted; and
a control unit adapted to:
obtain information regarding a surface topography of said first surface and said local surface of said workpiece;
determine, based on said information, heights h₁; h₂; h₃ of a plurality of deposits of a viscous medium that is to be formed on at least one of said first surface and said local surface, such that said plurality of deposits forms a connection between said component and said workpiece upon placing said component on the workpiece; and
cause the non-contact dispensing device to form each of the plurality of deposits of viscous medium by applying at least one droplet of the viscous medium using non-contact dispensing.

11. The system of claim 10, wherein said control unit is in communicative contact with a storage unit comprising information regarding a surface topography of at least one of a first surface of an component and a local surface of a workpiece.

12. The system of claim 10, wherein said non-contact dispensing device is selected from a jet printing device and a LIFT device.

13. The system of claim 10, further comprising a surface measurement device configured to perform measurements of at least one of said first surface and said local surface.

14. The system of claim 13, wherein said surface measurement device is arranged to perform measurements of said at least one of said first surface and said local surface while said non-contact dispensing device applies droplets of the viscous medium onto said at least one of said mounting surface and said local surface.

15. A storage medium comprising instructions which, when carried out by a control unit of a system for depositing a viscous medium, will bring a control unit of the system to:
obtain information regarding a surface topography of at least one of a first surface of a component and a local surface of a workpiece onto which said component is to be mounted; and
determine, based on said information, heights of a plurality of deposits of a viscous medium that is to be deposited on at least one of said first surface and said local surface, such that said plurality of deposits forms a connection between said component and said workpiece upon placing said component on the workpiece; and
will bring a non-contact dispensing device of the system to form the plurality of deposits, based on the determined heights, on at least one of said first surface and said local surface by applying at least one droplet of the viscous medium using non-contact dispensing.
